(19) United States
(12) Patent Application Publication
(10) Pub. No.: US 2018/0095110 A1
(43) Pub. Date: Apr. 5, 2018

(54) COMPACT TESTING SYSTEM

(71) Applicant: XCERRA CORPORATION, BOSTON, MA (US)

(72) Inventors: BENJAMIN BROWN, PALO ALTO, CA (US); RUSSEL POFFENBERGER, PIONEER, CA (US)

(21) Appl. No.: 15/281,966

(22) Filed: Sep. 30, 2016

(51) Int. Cl. G01R 1/067; G06F 13/40; G06F 13/42; G01R 31/28

(52) U.S. Cl. CPC G01R 1/067; G06F 13/4068; G06F 2213/0042; G01R 31/28; G06F 13/4282

(57) ABSTRACT

An automated test platform includes a CPU subsystem housed in an enclosure and configured to execute an automated test process. A test head is housed in the enclosure and is configured to apply one or more test signals to a device under test. A power supply is housed in the enclosure and is configured to provide electrical power to the CPU subsystem and the test head.

### TECHNICAL FIELD

This disclosure relates to automated testing equipment and, more particularly, to compact automated testing equipment.

### BACKGROUND

Automated test equipment systems may be used to test various electronic components, which are often referred to as DUTs. Such systems may automate the testing of such components, wherein a component may be subjected to a battery of different tests in some form of logical fashion. Additionally, such systems may provide further levels of automation, wherein the components being tested may be subjected to automated testing procedures, wherein measurements are taken at various test points of the DUT. Further, additional automation may be provided, wherein DUTs are automatically swapped out (upon completion of a testing procedure) and replaced with a component that is yet to be tested.

Unfortunately, such automated test equipment may be large and complex in nature, often spanning multiple enclosures that need to be electrically coupled and take up considerable floor space.

### SUMMARY OF DISCLOSURE

In one implementation, an automated test platform includes a CPU subsystem housed in an enclosure and configured to execute an automated test process. A test head is housed in the enclosure and is configured to apply one or more test signals to a device under test. A power supply is housed in the enclosure and is configured to provide electrical power to the CPU subsystem and the test head.

One or more of the following features may be included. An interconnection platform may be configured to couple the CPU subsystem and the test head. The interconnection platform may include a PCIe bus that is configured to allow the CPU subsystem and the test head to communicate via PCIe communication standards. The interconnection platform may include a USB bus that is configured to allow the CPU subsystem and the test head to communicate via USB communication standards. The interconnection platform may be configured to allow the automated test platform to interface with an external computing device. The CPU subsystem may include one or more of a personal computer, a server computer, a series of server computers, a mini computer or a single-board computer. The automated test platform may be configured to be spatially manipulated by a manipulator system. The manipulator system may be configured to move the automated test platform in the X axis, the Y axis and/or the Z axis. The manipulator system may be configured to rotate the automated test platform about the X axis, the Y axis and/or the Z axis. The automated test platform may be configured to interface with a handler system. The handler system may be configured to automate the testing of the device under test.

In another implementation, an automated test enclosure includes a CPU subsystem configured to execute an automated test process. A test head is configured to apply one or more test signals to a device under test. An interconnection platform is configured to couple the CPU subsystem and the test head. A power supply is configured to provide electrical power to the CPU subsystem, the test head and the interconnection platform.

One or more of the following features may be included. The interconnection platform may include a USB bus that is configured to allow the CPU subsystem and the test head to communicate via USB communication standards. The interconnection platform may be configured to allow the automated test enclosure to interface with an external computing device. The CPU subsystem may include one or more of a personal computer, a server computer, a series of server computers, a mini computer or a single-board computer. The automated test enclosure may be configured to be spatially manipulated by a manipulator system. The automated test enclosure may be configured to interface with a handler system.

In another implementation, an automated test platform includes a CPU subsystem housed in an enclosure and configured to execute an automated test process. A test head is housed in the enclosure and is configured to apply one or more test signals to a device under test. An interconnection platform is housed in the enclosure and is configured to couple the CPU subsystem and the test head. A power supply is housed in the enclosure and is configured to provide electrical power to the CPU subsystem, the test head and the interconnection platform. A manipulator system is configured to spatially manipulate the enclosure.

One or more of the following features may be included. The manipulator system may be configured to move the automated test platform in the X axis, the Y axis and/or the Z axis. The manipulator system may be configured to rotate the automated test platform about the X axis, the Y axis and/or the Z axis.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a diagrammatic view of an automated test platform.

Like reference symbols in the various drawings indicate like elements.

### DETAILED DESCRIPTION OF THE PREFERRED EMBODIMENTS

### System Overview:

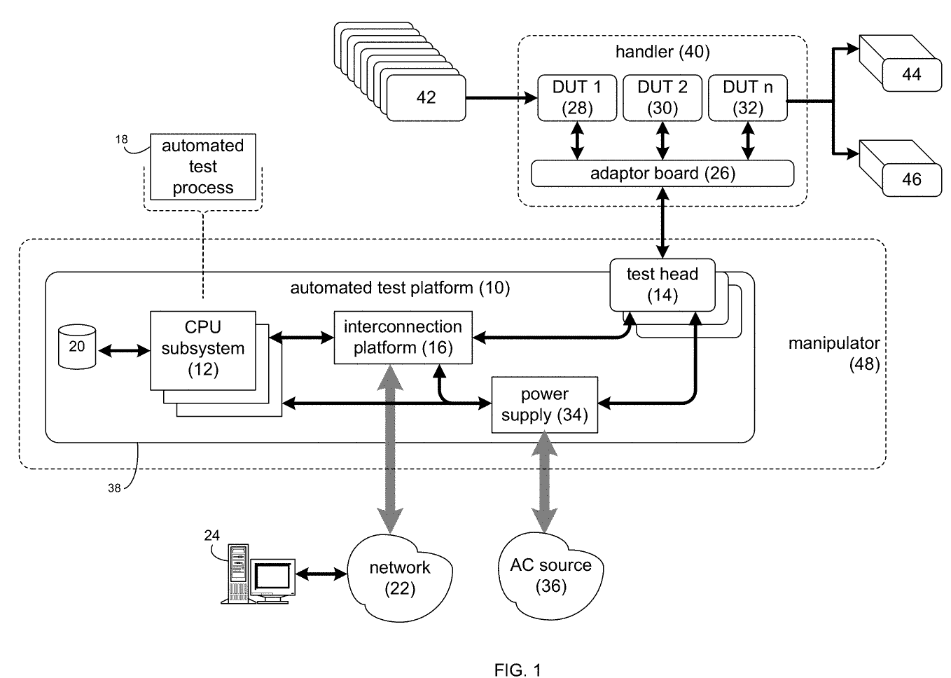

Referring to FIG. 1, there is shown automated test platform 10. Examples of automated test platform 10 may include, but are not limited to, systems that automate the verification and validation of devices under test (DUTs). As discussed above, automated test equipment systems (e.g. automated test platform 10) may be used to test various electronic components in an automated fashion. Typically, the devices under test are subjected to a battery of different tests, wherein the testing procedures are automated in a logical fashion. For example, during the testing of a power supply, the power supply may be subjected to varying voltage levels and varying voltage frequencies. Further, during the testing of a noise canceling circuit, such a circuit may be subjected to varying levels and frequencies of noise to confirm the satisfactory performance of the same.

Automated test platform 10 may include one or more central processing units (e.g. CPU subsystem 12) and one or more test heads (e.g. test head 14), which may be coupled together via interconnection platform 16 (e.g., a PCIe bus or a USB bus).

If configured as a PCIe bus, interconnection platform 16 may allow for test head 14 and CPU subsystem 12 to communicate via interconnection platform 16 using the PCIe communication standards. As is known in the art, PCIe (Peripheral Component Interconnect Express) is a high-speed serial computer expansion bus standard designed to replace older bus systems (e.g., PCI, PCI-X, and AGP). Through the use of PCIe, higher maximum system bus throughput may be achieved. Other benefits may include lower I/O pin count, a smaller physical footprint, better performance-scaling for bus devices, a more detailed error detection and reporting mechanism, and native plug-n-play functionality.

If configured as a USB bus, interconnection platform 16 may allow for test head 14 and CPU subsystem 12 to communicate via interconnection platform 16 using the USB communication standards. As is known in the art, Universal Serial Bus (USB) is an industry standard that defines the cables, connectors and communications protocols used in a bus for connection, communication, and power supply between computers and various electronic devices/components.

Examples of CPU subsystem 12 may include but are not limited to a personal computer, a server computer, a series of server computers, a mini computer or a single-board computer. CPU subsystem 12 may execute one or more operating systems, examples of which may include but are not limited to: Microsoft Windows Server™; Redhat Linux™, Unix, or a custom operating system, for example.

While in this particular example, automated test platform 10 is shown to include three CPU subsystems, this is for illustrative purposes only and is not intended to be a limitation of this disclosure, as other configurations are possible. For example, the number of CPU subsystems utilized within automated test platform 10 may be increased or decreased depending upon the anticipated loading of automated test platform 10.

CPU subsystem 12 may execute one or more automated test programs (e.g. automated test process 18), wherein automated test process 18 may be configured to automate the testing of various devices under test. Through the use of automated test process 18, an administrator (not shown) of automated test platform 10 may define and execute testing procedures/routines for the various devices under test.

For example, automated test process 18 (and test head 14) may be configured to e.g., apply certain test signals to a device under test while monitoring certain output voltages or digital signals being produced by the device under test during the application of those test signals. Accordingly, if the device under test is a power supply circuit, automated test process 18 (and test head 14) may apply a line voltage to the power supply circuit while measuring an output voltage being generated by the power supply circuit. Alternatively, if the device under test is an analog to digital controller that is configured to produce various digital output signals in response to various analog input signals, automated test process 18 (and test head 14) may be configured to apply various permutations of those analog input signals to the analog to digital controller while measuring the various digital output signals produced by the same.

The instruction sets and subroutines of automated test process 18, which may be stored on storage device 20 coupled to/included within CPU subsystem 12, may be executed by one or more processors (not shown) and one or more memory architectures (not shown) included within CPU subsystem 12. Storage device 20 may include but is not limited to: a hard disk drive; an optical drive; a RAID device; a random access memory (RAM); a read-only memory (ROM); and all forms of flash memory storage devices.

CPU subsystem 12 may be connected to one or more networks (e.g., network 22), examples of which may include but are not limited to: a local area network, a wide area network, an intranet or the internet, for example. Accordingly, CPU subsystem 12 may be administered and/or controlled via network 22. Therefore, an administrator (not shown) may use a remote computer (e.g., remote computer 24) coupled to network 22 to define and/or administer various testing procedures and/or routines via automated test process 18.

Automated test platform 10 may be configured to work with adapter board 26. wherein adapter board 26 may be configured to adapt test head 14 (which may be universal) to the particular type of device under test. For example, test head 14 may be a universal connector assembly that is configured to provide signals to and/or read signal from the device under test. Specifically, automated test platform 10 and/or automated test process 18 may be configured to e.g., provide one or more signals to the device under test and read the signals present at various test points of the device under test during these procedures.

In this particular example, adapter board 26 is shown being configured to accommodate a plurality of devices under test, namely devices under test 28, 30, 32 (representing DUTs 1-n). However, this is for illustrative purposes only and is not intended to be a limitation of this disclosure, as other configurations are considered to be within the scope of this disclosure. For example, the number of devices under test may be increased or decreased depending upon the design criteria of adapter board 26, test head 14, automated test platform 10 and/or automated test process 18. Alternatively, test head 14 may be configured to work without adapter board 26, wherein test head 14 may be configured to allow a single device under test (e.g., device under test 28) to directly plug into/couple with test head 14.

Automated test platform 10 may include power supply 34 that may be configured to receive AC power from AC source 36 and provide electrical power to e.g., test head 14, interconnection platform 16 and computing device 12. Examples of AC source 36 may include but is not limited to a 120 VAC source, a 240 VAC source, a 120/208 VAC 3-phase source, and a 277/408 VAC 3-phase source. In order to allow automated test platform 10 to have a smaller footprint and utilize less floor space, all components of automated test platform 10 may be housed/contained within a single enclosure (e.g., enclosure 38).

A handler system (e.g., handler system 40) may be configured to automate the testing of the devices under test (e.g., devices under test 28, 30, 32). For the following discussion, handler system 40 is considered to be a system that may perform various operations/procedures with respect to automated test platform 10, examples of which may include but are not limited to: a) the delivery of packaged parts to automated test platform 10 for testing and/or the delivery of unpackaged parts (i.e. a wafer) to automated test platform 10 for testing.

Specifically and for illustrative purposes, handler system 40 may be configured to maintain supply 42 of devices under test, wherein handler system 40 may be automated to e.g., insert devices under test 28, 30, 32 into adapter board 26, notify automated test process 18 that devices under test 28, 30, 32 are ready for testing so that automated test process 18 may implement the above-described testing procedures. Once these testing procedures are completed, automated test process 18 may know which (if any) of devices under test 28, 30, 32 failed the above-described testing procedures. Accordingly, automated test process 18 may inform handler system 40 which of devices under test 28, 30, 32 passed the above-described testing procedures and which of devices under test 28, 30, 32 failed the above-described testing procedures, wherein the “passing” devices under test may be removed from adapter board 26 and placed into “passing” bin 44 and the “failing” devices under test may be removed from adapter board 26 and placed into “failing” bin 46. At this point, handler system 40 may repopulate adapter board 26 with additional devices under test (from supply 42) so that automated test process 18 may initiate another round of testing.

As the alignment and positioning of test head 14 with respect to handler system 40 is critical for the proper operation of automated test platform 10, a manipulator system (e.g., manipulator system 48) may be configured to spatially manipulate automated test platform 10 (and test head 14) and properly position automated test platform 10 (and test head 14) with respect to handler system 40.

For example, manipulator system 48 may be configured to move automated test platform 10 up or down (in the Z axis), move automated test platform 10 left or right (in the X axis), and/or move automated test platform 10 forward or backward (in the Y axis) to properly align and position automated test platform 10 (and test head 14) with respect to handler system 40. Additionally, manipulator system 48 may be configured to rotate automated test platform 10 (and test head 14) with respect to any of these three axes.

### General:

As will be appreciated by one skilled in the art, the present disclosure may be embodied as a method, a system, or a computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. The computer-usable or computer-readable medium may also be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present disclosure may be written in an object oriented programming language such as Java, Smalltalk, C++ or the like. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network/a wide area network/the Internet.

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer/special purpose computer/other programmable data processing apparatus, such that the instructions, which execute via the processor of the computer or other programmable data processing apparatus, create means for implementing the functions/acts specified in the flowchart and/or block diagram block or blocks.

These computer program instructions may also be stored in a computer-readable memory that may direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The flowcharts and block diagrams in the FIGURES may illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the FIGURES. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. An automated test platform comprising:
a CPU subsystem housed in an enclosure and configured to execute an automated test process;
a test head housed in the enclosure and configured to apply one or more test signals to a device under test; and
a power supply housed in the enclosure and configured to provide electrical power to the CPU subsystem and the test head.

2. The automated test platform of claim 1 further comprising:
an interconnection platform configured to couple the CPU subsystem and the test head.

3. The automated test platform of claim 2 wherein the interconnection platform includes:
a PCIe bus that is configured to allow the CPU subsystem and the test head to communicate via PCIe communication standards.

4. The automated test platform of claim 2 wherein the interconnection platform includes:
a USB bus that is configured to allow the CPU subsystem and the test head to communicate via USB communication standards.

5. The automated test platform of claim 2 wherein the interconnection platform is configured to allow the automated test platform to interface with an external computing device.

6. The automated test platform of claim 1 wherein the CPU subsystem includes:
one or more of a personal computer, a server computer, a series of server computers, a mini computer or a single-board computer.

7. The automated test platform of claim 1 wherein the automated test platform is configured to be spatially manipulated by a manipulator system.

8. The automated test platform of claim 7 wherein the manipulator system is configured to move the automated test platform in the X axis, the Y axis and/or the Z axis.

9. The automated test platform of claim 7 wherein the manipulator system is configured to rotate the automated test platform about the X axis, the Y axis and/or the Z axis.

10. The automated test platform of claim 1 wherein the automated test platform is configured to interface with a handler system.

11. The automated test platform of claim 10 wherein the handler system is configured to automate the testing of the device under test.

12. An automated test enclosure comprising:
a CPU subsystem configured to execute an automated test process;
a test head configured to apply one or more test signals to a device under test;
an interconnection platform configured to couple the CPU subsystem and the test head; and
a power supply configured to provide electrical power to the CPU subsystem, the test head and the interconnection platform.

13. The automated test enclosure of claim 12 wherein the interconnection platform includes:
a USB bus that is configured to allow the CPU subsystem and the test head to communicate via USB communication standards.

14. The automated test enclosure of claim 12 wherein the interconnection platform is configured to allow the automated test enclosure to interface with an external computing device.

15. The automated test enclosure of claim 12 wherein the CPU subsystem includes:
one or more of a personal computer, a server computer, a series of server computers, a mini computer or a single-board computer.

16. The automated test enclosure of claim 12 wherein the automated test enclosure is configured to be spatially manipulated by a manipulator system.

17. The automated test enclosure of claim 12 wherein the automated test enclosure is configured to interface with a handler system.

18. An automated test platform comprising:
a CPU subsystem housed in an enclosure and configured to execute an automated test process;
a test head housed in the enclosure and configured to apply one or more test signals to a device under test;
an interconnection platform housed in the enclosure and configured to couple the CPU subsystem and the test head;
a power supply housed in the enclosure and configured to provide electrical power to the CPU subsystem, the test head and the interconnection platform; and
a manipulator system configured to spatially manipulate the enclosure.

19. The automated test platform of claim 18 wherein the manipulator system is configured to move the automated test platform in the X axis, the Y axis and/or the Z axis.

20. The automated test platform of claim 18 wherein the manipulator system is configured to rotate the automated test platform about the X axis, the Y axis and/or the Z axis.
